(19) United States
(12) Patent Application Publication
(10) Pub. No.: US 2007/0082128 A1
(43) Pub. Date: Apr. 12, 2007

(54) Method for coating a substrate

(75) Inventors: Roland Dittmeyer, Oberursel (DE); Martin Reif, Frankfurt (DE)

Correspondence Address: CROWELL & MORING LLP;INTELLECTUAL PROPERTY GROUP, P.O. BOX 14300, WASHINGTON, DC, 20044-4300, US

(73) Assignee: DECHEMA Gesellscaft fur Chemische Technik und Biotechnologie e.v., FRANKFURT (DE)

(21) Appl. No.: 10/547,736

(22) PCT Filed: Mar. 2, 2004
(86) PCT No.: PCT/DE04/00390

§ 371 Date: Nov. 1, 2006

(30) Foreign Application Priority Data
Mar. 3, 2003 (DE) 103 09 359.1

(51) Int. Cl. C23C 16/00; B05D 7/00

(52) U.S. Cl. 427/248.1; 427/212

(57) ABSTRACT

The invention relates to a method for coating a substrate with a metal or a metallic compound. According to said method, a metallo-organic parent compound and a substrate to be coated are introduced into a receptacle. Before the coating process, an organic solubilizer for the metal-organic parent compound is applied to the substrate. The receptacle containing the substrate and the metallo-organic parent compound is placed in an oven for approximately two hours at a temperature of 300° C. In this way, the desired coating is obtained.

The invention relates to a method of coating a substrate with a metal or a metallic compound, by which the substrate is coated by means of a gaseous organometallic parent compound.

Such coating methods are generally known and used as CVDs (chemical vapor depositions). Chemical vapor deposition is generally used in various manners for the deposition of thin films. Metals, such as silicon, can be deposited in the production of semiconductors; or different metals can be deposited in the production of strip conductors; or metal oxide compounds can be deposited as an anticorrosion layer; and hard material layers can be deposited for surface hardening.

Mainly two types of thermal reactors are used for the chemical vapor deposition of organometallic compounds; these are the hot-wall reactor and the cold-wall reactor. In the case of the hot-wall reactor, the substrate to be coated as well as almost the entire reactor are brought to a reaction or deposition temperature from the outside by way of an oven. In most cases, the precursor gas is transported with an inert or reactive (contains, for example, H₂) carrier gas to the substrate and is English Translation thermally decomposed there. The decomposition can take place either in the gaseous phase, in which case reactive intermediate stages are formed which subsequently are adsorbed on the substrate and continue to react there to form the desired product; or the precursor is first adsorbed on the substrate and then disintegrates on the surface by the feeding of energy into the desired products. Forming gaseous decomposition products are subsequently again transported with the carrier gas out of the reaction space. An important disadvantage of hot-wall CVD reactors is the simultaneous heating of the reactor and the substrate from the outside. As a result, the deposition takes place not only on the substrate but also on the reactor walls. In the case of cold-wall reactors, the reactor is not heated from the outside by way of an oven, but the deposition takes place on a heated substrate surface. For this purpose, the substrate has to be heated in a targeted manner. The heating of different geometries may be particularly difficult in this case with respect to the equipment.

Material transport processes have a decisive influence on the deposition in the case of both thermal reactor types. They depend, among other conditions, on the flow relationships in the reactor and thus on the reactor geometry as well as on a large number of reaction conditions (temperature, precursor concentration, reactor pressure, carrier gas flow, etc.). Generally, an optimization of the deposition process is extremely tedious and difficult. A uniform coating cannot be achieved in the case of larger substrate surfaces because the precursor concentration changes along the length of the reactor. The concentration and therefore the depositing rate is high at the reactor inlet, but the concentration and the depositing rate decrease toward the end. Because of an incomplete decomposition or deposition of the precursor, a large portion, in addition, leaves the reaction space unused together with the carrier gas.

In addition to the thermal CVD process, there is also the photo-supported and the plasma-supported chemical vapor deposition. In the former, light, preferably laser light, is used for the decomposition of the precursor and therefore for building up the layer. In the case of the plasma-supported chemical vapor deposition, electrons are used as the energy source, which are generated in an electric high-frequency field. The precursor molecules are excited by impacts by means of the electrons. Radicals are thereby generated which arrive on the substrate surface and form the layer to be deposited there. The actual advantage of the plasma-supported chemical vapor disposition is the deposition temperature which is lower in contrast to the thermal decomposition of the precursor. However, the plasma-supported and the photo-supported chemical vapor depositions have the same disadvantages as the thermal deposition. In addition, higher equipment-related expenditures are required.

The classical deposition method of the catalyst preparation is the wet impregnation. For this purpose, salts or other compounds are dissolved in water or organic solvents and applied to a carrier material. After the vaporization of the solvent, the catalytically active constituent is frequently fixed on the carrier by calcination and is activated in an additional step. Chemically inert materials, which have no active centers on the surface and only a low porosity, are very difficult to coat by means of wet impregnation. In addition, during the drying, large crystals may form at individual points as a result of the contraction of the liquid and the formation of drops. On the whole, in the case of a wet impregnation, such materials exhibit an insufficient and non-uniform deposition of the active constituents, a deficient fixing on the carrier surface and a low catalytic activity.

U.S. Pat. No. 4,870,030 describes a CVD process in which, in addition to the carrier gas with the precursor, a second gas flow is used which consists of a noble gas or hydrogen. Before entering the reactor, this second gas flow is excited in a high-frequency field (generating of plasma). The two gases impact on one another in the reactor. By providing the activated gas, temperature-sensitive semiconductor substrates can be coated at lower temperatures.

U.S. Pat. No. 6,132,514, U.S. Pat. No. 6,040,010 and U.S. Pat. No. 6,306,776 report on an intensified deposition of silicon or titanium films on semiconductor wafers, in the case of which a catalyst is used, such as ruthenium, rhodium, palladium, osmium, iridium, platinum, gold, silver, etc., in order to activate at 500 to 600° C. a reactive gas which contains hydrogen or can release it, such as H₂, HCl, SiH₄. The thus activated gas and the carrier gas charged with the precursor are individually guided from two different sides into the CVD reactor. As a result, the metals to be deposited can be deposited on the semiconductor materials also at lower temperatures.

U.S. Pat. No. 5,403,620 describes a CVD process which can also be operated in a plasma-supported or laser-induced manner and in the case of which organic tungsten compounds are deposited together with small amounts of catalytically acting substances (for example, organoplatinum compounds) in the presence of hydrogen. By using these small amounts of catalytic metal, tungsten films of a higher purity, that is, with fewer contaminations with carbon or foreign atoms, are obtained.

U.S. Pat. No. 5,130,172 explains the selective deposition of organometallic constituents, such as trimethylcyclopentadienyl platinum, in the presence of hydrogen as the reduction gas on semiconductor wafers which contain tungsten or silicon/tungsten compounds. The deposition of the platinum on tungsten takes place at clearly lower temperatures in comparison to surfaces, such as SiO₂, Si₃N₄, Si and GaAs. By controlling the substrate temperature, platinum can therefore be selectively deposited on tungsten or silicon/tungsten layers.

In International Patent Application WO 01/78123A1, a process is described in which iodine or iodine-containing compounds are used as surface-active substances. The iodine catalyzes the decomposition of the organometallic Cu(I)-hexafluoroacetyl acetonate vinyl trimethylsilane precursor. As a result, the deposition temperature is reduced and copper is selectively deposited at the points with iodine. This process permits the production of copper strip conductors.

In the case of [Langmuir 1997, 13, 3833-3838], Jeon et al. describe a process in which strip conductors made of palladium, platinum or copper in a CVD cold-wall reactor made of high-grade steel are deposited on substrates made of TiN, In₂O₃/SnO₂, SiO₂ on Si, sapphire or borosilicate glass. For this purpose, thin films of octadacyltrichlorosilane are first printed by microcontact printing onto the substrates. Subsequently, the metal precursors are selectively deposited on the imprinted films.

German Published Patent Application DE 19607437A1 describes a method of producing Pd shell catalysts. As an example, palladium acetate is dissolved as an organometallic compound in toluol and is subsequently applied to spherical porous catalyst carries, for example, made of aluminum oxide. The impregnating time determines the penetration and thus the thickness of the shell-shaped catalyst layer. When a palladium salt dissolved in aqueous solvents is used, a uniform continuous coating of the catalyst pellet with palladium is obtained. By the use of organometallic compounds dissolved in organic solvents, such as benzene, toluol, xylol, methanol or tetrahydrofurane, shell catalysts can be produced by wet impregnation or in a spraying process.

German Published Patent Application DE 19827844A1 describes a CVD method for producing Pd/Au shell catalysts on porous formed carrier bodies. Suitable noble metal precursors are deposited by way of the vapor phase on the carrier and are subsequently thermally or chemically reduced to the metal and thereby fixed on the carrier. These thus produced Pd/Au shell catalysts can preferably be used during the vinyl acetate synthesis according to the Wacker method. According to information described in greater detail in the patent, it is to be possible to control the shell thickness by means of the CVD process parameters.

In German Published Patent Application DE 10064622A1, a method is claimed for the wet impregnation of ceramic asymmetrical tube-shaped membranes with catalytic metals. For the coating, the ceramic membrane is placed in a rotary vaporizer in which the aqueous impregnating solution is situated. By the application of a vacuum and while rotating the vaporizer, the membrane is successively coated with the active constituents tin and palladium. In this case, a large portion is deposited in the macroporous carrier of the membrane. However, only the coating of the microporous cover layer of the asymmetrical membrane is desirable. In addition, the deposited particles are only partially firmly connected with the carrier surface. The thus produced membranes are used as a catalytic contactor/diffusor for the removal of nitrate and nitrite with hydrogen as a reducing agent from contaminated water.

Summarizing, it can be stated that most of the described CVD methods are used for depositing thin films and cannot be used for producing microdispersed catalysts. In addition, the necessary CVD reactors require very high equipment-related expenditures and are therefore very expensive. The process parameters have to be precisely observed in order to obtain the desired deposition. A coating of large components by means of the chemical vapor deposition is difficult to implement, and a transfer of laboratory systems to a large technical scale results in considerable difficulties because of the different flow conditions. By means of wet impregnation, only little material can be deposited on an inert carrier. Further, the coating is non-uniform and the deposited particles are not firmly connected with the surface. Also, by means of the conventional CVD methods or by wet impregnation, the point at which the catalytic constituents are to be deposited on a carrier can hardly be controlled or can be only poorly controlled.

Demand therefore exists for a simple and cost-effective coating method for the deposition of organometallic starting materials, particularly for the deposition of catalytically active metals or other catalytically active constituents in a microdispersed form into porous inorganic carrier materials, by means of which inert materials or materials with a small surface can also be coated in a uniform and reproducible manner.

According to the invention, this problem can be solved in that, before the coating by means of the organometallic parent compound, an organic solubilizer for the organometallic parent compound is applied to the substrate.

The invention is a newly developed CVD method. The carrier material to be coated is first pretreated with an organic solubilizer. For example, semisolid inert paraffins with melting points or softening ranges preferably between 30° C.-150° C. and boiling points or vaporization ranges between 80° C.-300° C., or any other, also liquid organic compounds with boiling points of up to 300° C. can be used as organic solubilizers. Clear white vaseline was found to be particularly suitable. The vaseline can be applied in any manner by means of a brush, in the heated condition by spraying or simple manually. The chemical vapor deposition of an organometallic precursor is then not carried out in a conventional hot- or cold-wall reactor but in a glass receptacle which can be evacuated, for example, a glass tube which can be evacuated and has a ground section for the connection of a glass tap. The porous carrier material to be coated, which had previously been treated by means of the organic solubilizer, is introduced into the glass receptacle vessel together with the CVD precursor. By way of a connected glass tap, the evacuation of the glass receptacle takes place by means of a vacuum pump. Then the evacuated receptacle is placed in an oven whose temperature is gradually increased. During the heating of the substrate, the organic solubilizer is uniformly distributed. The organometallic precursor to be deposited is first sublimated with the rising temperature and then dissolves preferably in the organic solvent. Subsequently, the solubilizer vaporizes with a further increasing temperature (approximately 200° C.). The chemical vapor deposition takes place within a time period of approximately 2 hours. Sufficient time is therefore given to the precursor to sublimate, to be transported to the carrier surface by diffusion, to adsorb on the surface of the carrier or to dissolve in the organic solvent and to then disintegrate. As a result, the material transport operations as well as the flow conditions and the reactor geometry are no longer decisive. In addition, unused precursor is not transported away from the substrate by means of a carrier gas. Larger substrates can also be uniformly coated in this manner without any problem. As a result, the organometallic precursor is deposited on the carrier to be coated where previously the organic solubilizer had been situated. Only a small portion of the organometallic precursor is deposited on the glass walls. By means of this coating method, the depositing efficiency can clearly be increased; for example, for palladium, depositing rates of 60% to 90% are reached. This is particularly significant in the case of expensive noble metal precursors. The site of the coating as well as the penetration depth into a porous structure can, in addition, be controlled in a targeted manner by the prior application of the solubilizer (quantity, penetration time). Inert materials with a low specific surface can also be coated. In addition, after the coating, a firm connection exists between the deposited metal and the substrate. A leaching and therefore the loss of the catalytic constituent when liquid reaction mixtures are used is therefore prevented. The metal to be deposited is deposited on the carrier in the form of small metallic clusters. By means of this method, microdispersed catalysts can therefore also be produced.

By means of the method according to the invention, in addition to metals, other catalytic constituents can also be deposited. Further, not only porous inorganic materials can be coated but the deposition of catalytic constituents can also take place on non-porous rough surfaces. The method according to the invention was found to be particularly suitable for the coating of porous ceramic or carbon-containing membranes with catalytically active metals.

By means of the following detailed examples, the invention will be explained more precisely and the advantages of the invention will be demonstrated.

### EXAMPLE 1

### Discovery of the Invention

Several attempts to deposit palladium with palladium(II) hexafluoroacetyl acetonate as an organometallic precursor on ceramic tube-shaped membranes with an outside diameter of 10 mm and a length of 10 cm showed that a deposition in a hot-wall reactor supplies only unsatisfactory results. A uniform coating along the entire length or the circular outer surface of the membrane could not be achieved. Because of the changing precursor concentration, more was deposited on the one side toward the reactor inlet than toward the end of the membrane. In addition, a large portion of the precursor was removed again unused from the reactor with the carrier gas. In order to prevent this, the CVD coating was transferred into a glass tube which can be evacuated. There also, only little palladium was deposited on the inert membrane surface (α-Al₂O₃). However, during coating tests, deposits of palladium were surprisingly found on the exterior side of the ceramic membrane, where previously traces of fat had been applied. The coating had therefore taken place where the fat was located because the organometallic precursor had preferably dissolved therein.

The idea now consisted of increasing the depositing rate and intentionally controlling the deposition site by a targeted application of an organic solubilizer.

### EXAMPLE 2

### Chemical Vapor Deposition of Palladium on Ceramic Membranes

The following example describes the advantageous deposition of palladium on tube-shaped ceramic membranes in the form of small metal clusters for producing catalytically active membranes but can also easily be transferred to other catalytically active metals, such as platinum, rhodium, silver, gold, nickel, copper, zinc, tin, etc. or to other ceramic or carbon-containing substrates to be coated.

The ceramic membranes to be coated have an asymmetrical structure. They consist of a macroporous carrier made of α-Al₂O₃ and a thin, microporous layer on the exterior side of the membrane. The microporous cover layer may consist of various ceramic materials, such as Al₂O₃, ZrO₂, TiO₂, etc. The pores of the cover layer typically of a mean pore diameter of between 5 nm and 400 nm. The macroporous carrier typically has mean pore diameters of approximately 3 μm. The membranes are commercially available and are normally used in ultra- and microfiltration. If the cover layer of these membranes is coated with catalytically active metals or other catalytically active constituents, these membranes can be used for gas-liquid reactions, for example, for hydrogenation reactions with hydrogen gas. For this purpose, the gaseous starting material is guided into the interior of the tube-shaped membrane and thus by way of the macroporous carrier onto the catalytic layer. The second starting material is transported as a liquid or dissolved in a liquid from the exterior side to the catalytic layer. As a result of capillary action, the liquid is sucked into the pores of the microporous layer. However, the pressure in the interior of the membrane is so high that no liquid is situated in the macroporous carrier. The two starting materials are therefore transported onto the catalytic layer from two different sides. It is an object of the coating to deposit the catalytically active constituents only in the microporous cover layer and not in the macroporous carrier of the membrane because the catalytic constituents can come in contact with the two starting materials only in the cover layer. Typically, tube-shaped ceramic membranes with an outside diameter of 10 mm and a length of 10 cm are used. The thickness of the cover layer amounts to 1 μm to 40 μm.

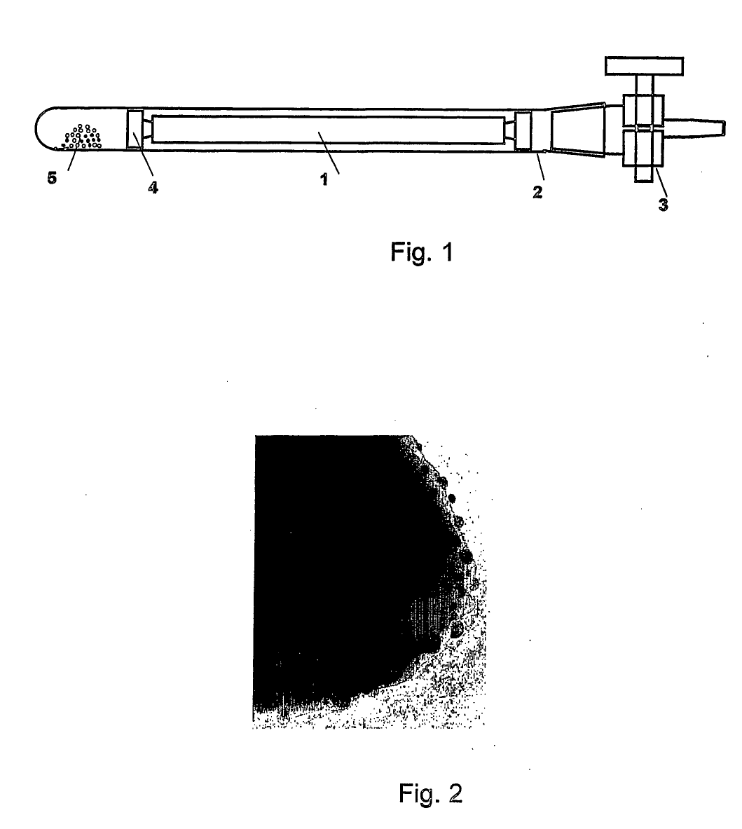

Before the coating of the membrane with palladium, the weight of the membrane is determined by weighing so that later the quantity of the deposited palladium can be determined. In order to deposit the palladium only in the exterior microporous layer, the membrane is pretreated by a solubilizer. It was found that clear white vaseline is particularly suitable. The vaseline is applied to the exterior side of the membrane, is uniformly distributed and a little later is completely removed again with tissue paper. It is important that, after the application, the surface vaseline is completely removed again so that only a small amount of vaseline will remain in the pores of the porous membrane. Two conical glass stoppers with a teflon seal (4) are fitted into the ends of the tube-shaped membrane (1, see FIG. 1). 100 mg of the palladium precursor (5) is fed into a glass tube (2) of a volume of approximately 25 ml with a ground section for connecting a glass cock (3). Palladium(II)-hexafluoroacetyl acetonate (Aldrich 401471) is used as the palladium precursor. The membrane with the glass stopper is transferred into the glass tube. The outside diameter of the glass stoppers is slightly larger than the diameter of the membrane. As a result, it is prevented that the ceramic membrane in the glass tube rests on the glass wall. This also avoids that the organic precursor penetrates into the tube interior. The glass tube is then closed by means of a glass cock (3). For sealing off the ground-in connection, high-temperature grinding fat is used. The connection between the glass tube and the glass cock is secured by means of a metal clamp. Subsequently, the air is removed from the glass tube by means of a vacuum pump and a vacuum of approximately 3 mbar absolute pressure or less is generated in the glass tube. After the closing of the glass cock, the evacuated glass tube is transferred into a laboratory oven whose temperature is at 150°. Within 30 minutes, the temperature of the oven is raised to 250° C. After the temperature has reached 250° C., the glass tube stays in the oven for another 2 hours. During these 2¼ hours in the oven, the vaseline becomes liquid and distributes in the pore system of the microporous membrane layer. As a result of capillary action, the liquid vaseline is, however, held in the smaller pores of the microporous layer and does not penetrate into the macroporous carrier material provided only a little vaseline is available. The organometallic precursor sublimes and dissolves in the vaseline. The vaseline simultaneously vaporizes with time. The palladium(II)-hexafluoroacetyl acetonate disintegrates into metallic palladium and an organic residue. As a result, palladium is obtained at points where the vaseline had previously been situated. As desired, the palladium is thereby deposited only in the thin microporous cover layer of the membrane but not in the carrier material. Subsequently, the hot glass tube is removed from the oven and is opened in the fume chamber so that the vaporized vaseline and the gaseous organic products, which occur during the disintegration of the precursor, can escape.

The membrane is then heated in a high-temperature oven to a temperature of 400° C. in the air flow (heating rate 2 K (cal.)/min). As a result, possibly still existing organic residues are burned off the ceramic membrane. The black-gray palladium thereby oxidizes to brown palladium oxide. The membrane remains in the oven at 400° C. for four hours and is then cooled at 2 cal./min. to room temperature. The obtained palladium oxide subsequently has to be reduced again to metallic palladium. For this purpose, the membrane is transferred to another glass tube. Hydrogen gas is introduced into the glass tube, the glass tube is closed and is placed in a laboratory oven having a temperature of 150° C. The membrane remains in the oven for 2 hours. As a result, the palladium oxide is reduced to palladium. After the cooling, the membrane is dried and can then be weighed for determining the deposited quantity of palladium.

In contrast to conventional CVD coating methods described in the literature, the described method is extremely simple. For a hot-wall reactor or a cold-wall reactor with a heated substrate, high equipment-related and control-related expenditures are required. The described method requires only a glass tube and a conventional laboratory oven. The technical expenditures and therefore the costs for the coating are therefore significantly lower. The described CVD method permits a uniform coating of the ceramic membranes over the entire length of the membrane because the CVD coating takes place slowly in the closed glass tube and the precursor has sufficient time to be transported to the substrate by diffusion. In the case of a conventional hot-wall reactor, the organometallic precursor is transported to the substrate by means of a carrier gas; that is, the precursor has only a certain brief dwell time in the reactor. Simultaneously, the concentration of the precursor and thus the depositing rate changes along the length of the reactor. At the reactor inlet, the precursor concentration and thus the depositing rate is high, but the concentration and the depositing rate become lower toward the end of the reactor. In the case of a ceramic tube membrane, this means that a lot of palladium is deposited on one end of the membrane and little palladium is deposited on the other end. In addition, the dwell time in the reactor may be too short and thus unused precursor may be transported again out of the reactor by means of the carrier gas. Furthermore, in the case of the conventional hot-wall reactor, the hot walls of the reactor are easily coated. On the whole, in the case of the slow CVD deposition process according to the invention and when using a solubilizer, such as vaseline, very high depositing rates of 60% to 90% are reached in comparison to conventional CVD methods, and the deposition takes place in a uniformly distributed manner over the entire surface of the membrane. Specifically in the case of expensive noble metals, such as palladium, this is of special significance.

### EXAMPLE 3

### Coating of Inert Materials and Characterization of the Deposited Metal Particles by Means of Transmission Electron Microscopy

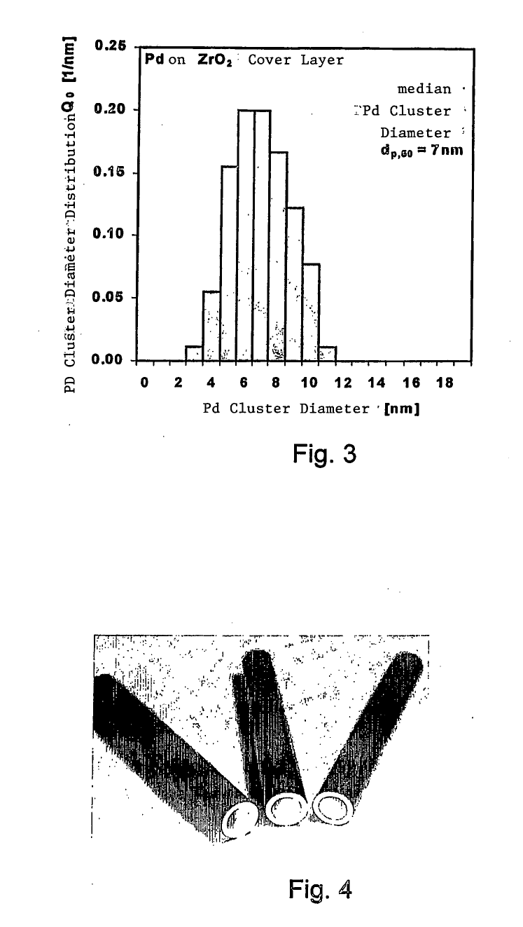

By means of the coating method according to the invention, inert ceramic materials, such as α-Al₂O₃, or materials with a low specific surface can be coated. A ceramic membrane with a cover layer made of α-Al₂O₃ was coated with palladium according to the specification of Example 2. In the case of the subsequent use of the membrane for the nitrate or nitrite reduction in an aqueous reaction mixture, no leaching of the palladium and also no deactivation of the catalytically active membrane could be observed over a period of 2 months. A subsequent characterization of the deposited palladium particles by means of a transmission electron microscope (TEM) could show that the metal clusters are firmly connected with the ceramic surface. The palladium particles are present in the form of hemispheres on the carrier material (see FIG. 2). Individual free-standing spherical metal clusters do not exist. As a result of the firm connection between the palladium clusters and the ceramic carrier, no palladium is lost during the reaction in aqueous or organic solvents. In addition, by means of a TEM characterization, by measuring the cluster diameters on a TEM picture, a metal cluster diameter distribution can be determined. FIG. 3 shows a typical distribution of the diameters of the palladium clusters on a ceramic membrane with a cover layer of ZrO₂. The median palladium particle diameter is 7 nm. The catalytic metal is therefore deposited in a finely distributed manner as nanoparticles on ceramic carriers. The coating method according to the invention is therefore suitable for the production of microdispersed catalysts.

### EXAMPLE 4

### Production of Dense Palladium Membranes for the Separation of Hydrogen from Gas Mixtures

In order to apply a dense, defectfree layer of palladium to a ceramic membrane or a sintered-metal membrane, an electroless wet-chemical deposition (electroless plating) can be used. For this purpose, palladium nuclei are first generated on the membrane surface in that the membrane is alternately dipped into a hydrochloric tin chloride solution (SnCl₂) and a hydrochloric palladium chloride solution (PdCl₂). This operation is repeated three to ten times. By the oxidation of the Sn²⁺-ions to Sn⁴⁺-ions, the palladium ions (Pd²⁺) are in this case reduced to elementary palladium. Subsequently, the excess tin chloride is removed again by rinsing with distilled water. This precoating supplies relatively large (approximately 100 nm to 200 nm) palladium particles in the membrane cover layer. In addition, the palladium particles are only insufficiently fixed on the membrane surface, and the coating of the membrane can take place only very non-uniformly. This is followed by the electroless wet-chemical deposition (electroless plating) of palladium with a coating solution of palladium chloride dissolved in ammonia water, which solution was stabilized by means of sodium EDTA. The reducing agents hydrazine and formaldehyde are successively added to this solution. Subsequently, a precoated membrane is placed in the coating solution and the solution is heated. In this case, palladium grows on the palladium nuclei formed during the precoating. Then, the membrane is rinsed with distilled water, is dried and is again placed in fresh coating solution. The coating operation is repeated until the desired layer thickness has been reached and, as a result, a gas-tight defectfree palladium layer has grown on the membrane. The membranes produced in this manner are used for the hydrogen separation from gas mixtures and can be used in the case of different technical reactions.

If the described precoating with the alternating addition of hydrochloric tin chloride solution (SnCl₂) and hydrochloric palladium chloride solution (PdCl₂) is replaced by the coating method according to the invention corresponding to Example 2, this has the following advantages: Lower quantities of palladium are sufficient for the coating, because, in the case of the CVD method, smaller palladium clusters (5 nm-15 nm, instead of 100 nm-200 nm) are generated in the membrane cover layer. In addition, the membrane is uniformly coated and the palladium clusters are present in a firmly fixed manner on the ceramic membrane or the sintered-metal membrane. Another advantage of the CVD method according to the invention is that palladium clusters can be deposited also on rough membrane surfaces (for example, on a sintered-metal membrane) in a uniform manner on the entire surface of the cover layer also at poorly accessible points because the liquid solubilizer is uniformly distributed over the entire surface. Coating tests have shown that, when the CVD method according to the invention is used as the precoating, significantly smaller amounts of palladium have to be deposited during the subsequent electroless plating in order to produce a tight palladium layer. Thus, palladium layer thicknesses of 10 μm are sufficient in order to produce a defectfree layer. In the case of the conventional method, layer thicknesses of approximately 20 μm are required. As a result, significant amounts of the expensive noble palladium metal are saved. In addition, the firm fixing of the palladium clusters deposited by means of the CVD method of the invention prevents a later chipping-off of the palladium layer which therefore decisively increases the service life of the membrane produced in this manner.

### EXAMPLE 5

### Control of the Deposition Site and Control of the Penetration Depth into a Porous Ceramic Structure

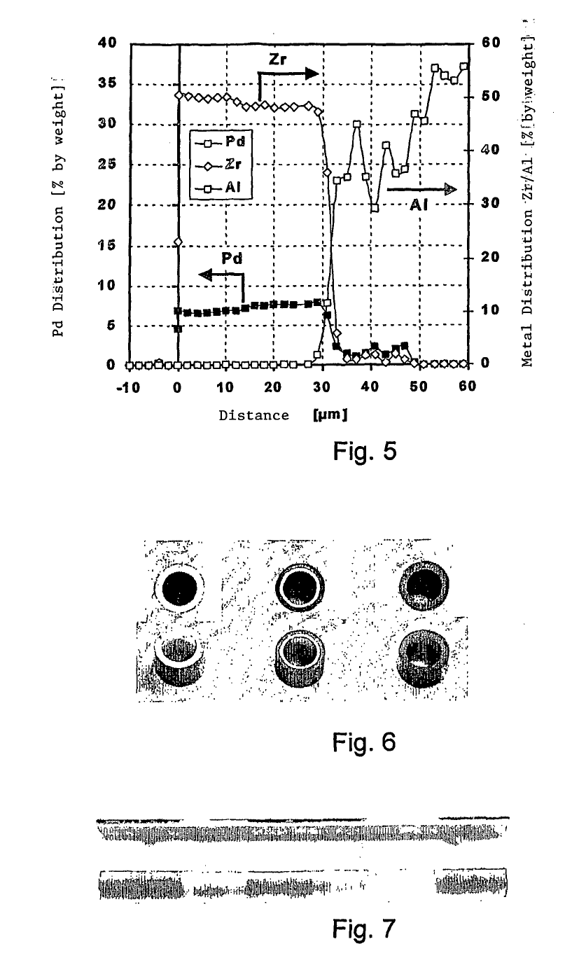

As described in Example 2, the liquid vaseline is distributed during the heating in the cover layer of the membrane. However, because of the capillary action, it is held in the small pores of the microporous layer and therefore does not penetrate into the macroporous structure of the carrier. It therefore becomes possible to deposit the palladium only in the microporous layer of the membrane but not in the carrier (see FIG. 4). This is not possible by means of conventional methods, such as the wet impregnation. In addition, electron beam micro-analysis tests (ESMA) have shown that the concentration of the deposited palladium inside the microporous layer is constant; that is, no concentration gradients occur toward the interior. FIG. 5 illustrates an ESMA analysis of a coated ceramic membrane with a ZrO₂ cover layer and a carrier of made α-Al₂O₃. The concentrations of Zr, Al and Pd are shown over the distance from the exterior side of the membrane. According to the method described in Example 2, 33.4 mg palladium were deposited on a tube-shaped membrane piece of a length of 10 cm. The analysis surprisingly shows that the palladium concentration in the ZrO₂ cover layer does not decrease from the outside toward the inside but that it extends in a relatively constant manner. The Pd concentration even rises slightly toward the inside. With the end of the ZrO₂ cover layer, the palladium content also decreases abruptly. Hardly any palladium is deposited in the aluminum carrier.

Conventional CVD coating techniques produce thin films on a substrate surface and are therefore surface-coating methods. By means of the CVD coating methods according to the invention, catalytic constituents can also be deposited into the depth. By varying the quantity of solubilizer, the penetration depth into a porous ceramic structure can be controlled during the coating. If more vaseline is used and the vaseline is allowed to penetrate into the carrier, the macroporous ceramic carrier can also be coated. The used quantity of vaseline, the time during which the vaseline can distribute and also the temperature determine the penetration depth of the vaseline and thus also the deposition of the palladium. FIG. 6 illustrates an example in which palladium was deposited at different depths into a ceramic membrane. A portion of the ceramic membrane is visible in FIG. 6, on the left, in the case of which the deposition of the palladium only took place in the cover layer. In FIG. 6, center and on the right, a macroporous ceramic carrier was partially or completely coated. The transition from to coated to the uncoated carrier in FIG. 6, center, is very pronounced. In order to allow the precursor to penetrate deeper into the ceramic membrane, a thicker layer of vaseline is applied to the exterior side of the membrane. During the subsequent heating of the membrane to approximately 80°, the vaseline liquefies and is completely taken in by the pore system of the ceramic membrane. Corresponding to the existing quantity of solubilizer, the pore system is filled from the outside toward the inside. The penetration of the solubilizer into a porous structure and thus the deposition of palladium can therefore mainly be influenced by the quantity of the solubilizer but also by the penetration time as well as the temperature existing at the time.

By the use of the vaseline, certain desired points can be coated on a ceramic or carbon-containing material. Other points may be omitted. The metal, for example, palladium to be deposited is finally deposited on inert materials always where previously the vaseline had been applied. FIG. 7 shows an example in which certain points on a porous ceramic carrier material made of α-Al₂O₃ are coated with palladium, while simultaneously other points were omitted. Previously, the solubilizer was applied only to the desired points. After the CVD coating in the glass tube, it was found that palladium had mainly deposited at the points where the solubilizer had previously been applied.

### EXAMPLE 6

### Modification of a Ceramic Membrane with a Carbon Layer and Subsequent CVD Coating with Palladium

A ceramic membrane made of α-Al₂O₃ or ZrO₂ has a very low specific inner surface. In order to produce a high surface in such a ceramic membrane, it can be modified by the insertion of a carbon layer with a high inner surface into the pore system. Subsequently, corresponding to Example 2, palladium or another catalytically active metal can be deposited on this carbon layer. By changing the carrier material, it is becomes additionally possible to alter the catalytic characteristics of the membrane. Thus, a carbon layer has more hydrophobic characteristics than a pure ceramic membrane.

For coating a ceramic membrane or another ceramic carrier with a carbon layer with a high specific inner surface, a polyfurfuryl alcohol resin first has to be produced. For this purpose, 100 ml of the monomer furfuryl alcohol (Fluka 48100) are placed in a 250 ml beaker. The alcohol is stirred with a magnetic stirrer, and subsequently 2 ml of a 65% nitric acid are added very slowly. The beaker is covered by a UR (infrared absorbing) glass but should not be closed, and the alcohol should remain in contact with the ambient air. The alcohol heats up to approximately 40° C. and the slightly green liquid darkens by the starting polymerization. The stirring of the alcohol is continued for a day. During this time, the acid-catalyzed polymerization takes place; the liquid becomes darker and more viscous. The next day, the resin, while being stirred, is slowly heated to 80° C. This temperature is maintained for an hour. Subsequently, the resin is allowed to cool down again while being continuously stirred, and the beaker remains covered by a UR glass. Among other this, the stirring has the purpose of preventing that the heat released during the polymerization causes a delay in boiling. The UR glass permits a return flow of the rising vapors and prevent a contamination of the resin. On the third and fourth day, the polyfurfuryl resin is again heated to 80° C.; the temperature is maintained for an hour and the cooling then takes place again. Subsequently, the stirring of the resin is continued for another two days. Finally, a dark-brown viscous polyfurfuryl alcohol resin is obtained which can be filled into a plastic bottle for storage. In this manner, the produced resin can be stored for several months.

By varying the polymerization conditions, polyfurfuryl resins of a different viscosity can be produced for different applications. For this purpose, the polymerization is to be carried out at 80° C. for different durations or with a differing frequency, or the polymerization is to be carried out at a lower or higher temperature. However, a temperature of 90° C. should not be exceeded since the released reaction heat can easily cause a delay in boiling. In addition, by mixing the resin with acetone, it can be diluted for certain applications.

The thus produced polyfurfuryl alcohol resin can now be applied in different manners to a ceramic membrane; for example, as a thin film for producing a gas separation membrane, or it can be deposited into the pores of the microporous layer, or it may be applied only to the pore walls of the microporous cover layer.

In order to coat only the pore walls of the microporous cover layer of a membrane with carbon, the pores of the membrane layer are first filled with polyfurfuryl alcohol resin. For this purpose, the resin can be applied to the membrane layer by means of a brush or in any arbitrary manner. After an effective time of approximately 20 minutes, the tube-shaped membrane is installed in a membrane holder. In this case, the ends of the membranes are sealed off by silicon seals. By blowing out the resin by means of compressed air at a pressure of from 18 bar to 20 bar, the resin is removed from the pores. A thin film remains only on the pore walls. The air flow through the membrane is maintained for another 30 minutes until the resin becomes dry or hard on the pore walls. The membrane is then transferred to a normal laboratory oven whose temperature is raised from room temperature to 250° C. within 60 minutes. At 250° C., the membrane remains in the air flow in the oven for 2 hours. In the process, the color of the resin changes from dark-brown to gray-black. After the cooling of the oven, the membrane is transferred into a tube-shaped oven with gas connections. The tube-shaped membrane is situated in the oven in a tube-shaped quartz tube and is carried by means of a ceramic holder such that it does not come in contact with the walls of the quartz tube. At a heating rate of 1 cal./min., the temperature of the oven is raised to 900° C., in which case a helium current (20 ml/min, ambient pressure) is guided with a volume fraction of 1% to 5% hydrogen through the quartz tube. At 900° C., the membrane remains in the oven under the gas flow for another 20 hours; then a cooling takes place again to room temperature at 1 cal./min. The forming carbon layer in the membrane has a very high specific surface of approximately 1,400 m²/g, has a cumulative micropore volume of approximately 0.5 cm₃/g (determined according to Horvath-Kawazoe, Dubinin-Radushkevich) as well as a cumulative mesopore volume of 1.35 cm³/g (determined according to Barret, Joyner and Halenda) and conducts the electric current. By changing the pyrolysis conditions (temperature, heating rate, flushing gas, etc.), however, the characteristics of the carbon layer can be influenced in a targeted manner.

Subsequently, the thus modified ceramic membrane with carbon in the pore walls can be coated corresponding to Example 2 with palladium or another catalytically active material or with another catalytically active compound.

### EXAMPLE 7

### Coating of Nonporous Rough Ceramic Surfaces

In addition to porous materials, nonporous surfaces, which have a certain surface roughness, can also be coated with catalytic metals or catalytic compounds. For this purpose, the organic solubilizer, for example, vaseline, is placed on the rough surface to be coated. During the subsequent CVD coating operation, the solubilizer becomes liquid as a result of heating and is thereby uniformly distributed in the rough surface. The organometallic precursor can dissolve in the organic solubilizer and subsequently disintegrates with the increasing temperature by thermal disintegration into the metal and the organic residue, while the solubilizer vaporizes simultaneously. The roughness of the surface in the nanometer or micrometer range is required in order to be able to absorb the solubilizer. By means of this application, for example, the ducts of a monolithic catalyst carrier or of a microstructure reactor can be coated.

### EXAMPLE 8

### Production of Shell Catalysts

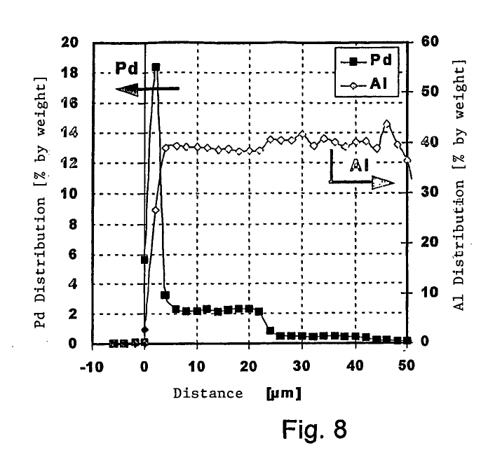

FIG. 8 illustrates the palladium distribution on a membrane to whose exterior side a thin layer (1 μm-2 μm) γ-Al₂O₃ had been applied. The measuring of the distribution took place by means of an electron beam micro-analysis. The coating of this membrane was carried out in the glass tube corresponding, to Example 2, however, without a preceding application of the solubilizer. The γ-Al₂O₃ has a high surface and active centers (OH groups on the surface) with which the precursor can react. As a result, palladium preferably deposits in the very thin γ-Al₂O₃ layer. Spherical catalyst pellets, to whose exterior side a thin γ-Al₂O₃ layer had been applied, could therefore, for example, also be coated in a targeted manner with palladium in this layer. Thereby shell catalysts with a thin catalytic layer on the exterior side of the catalyst pellets could be produced.

As illustrated in Example 4, the quantity of used solubilizer can control the penetration depth into a porous layer. This effect can also be utilized for producing shell catalysts, even if no layer with a high surface or active centers is present on the catalyst pellets to be coated. By the application of an organic solubilizer, for example, by a spraying process, to spherical porous catalyst carriers and a subsequent CVD coating, catalytically (catalytic) metals can be deposited on the catalyst pellets. The thickness of the forming catalytic shell can be controlled by way of the applied quantity of solubilizer as well as the effective time and temperature.

1. Method of coating a substrate with a metal or a metallic compound, by which the substrate is coated by means of a gaseous organometallic parent compound, characterized in that, before the coating by means of the organometallic parent compound, an organic solubilizer for the organometallic parent compound is applied to the substrate.

2. Method according to claim 1, characterized in that the organometallic parent compound as a solid substance and the substrate pretreated by means of the solubilizer are placed in a closed receptacle, that then the receptacle is evacuated and heated and, as a result, the organometallic parent compound is sublimed.

3. Method according to claim 1, characterized in that paraffins are used as organic solubilizers which have softening ranges of between 30° C.-150° C. and vaporization ranges of between 80° C. and 300° C.

4. Method according to claim 3, characterized in that white vaseline is used as the organic solubilizer.

5. Method according to claim 1, characterized in that palladium(II)-hexafluoroacetyl acetonate is used as the organometallic parent compound and, for coating the substrate, the receptacle with the parent compound and the substrate remains in an oven at a temperature of approximately 250° C. for several hours.

6. Method according to claim 1, characterized in that the organic solubilizer is selectively applied to the substrate.

7. Method according to claim 1, characterized in that the substrate is a porous ceramic membrane and the coating consists of catalytically active constituents.

8. Method according to claim 1, characterized in that the substrate to be coated is a porous ceramic membrane of a symmetrical or asymmetrical construction.

9. Method according to claim 1, characterized in that the substrate to be coated is a porous glass membrane of a symmetrical or asymmetrical construction.

10. Method according to claim 1, characterized in that the substrate to be coated is a porous metallic membrane of a symmetrical or asymmetrical construction.

11. Method according to claim 1, characterized in that the substrate to be coated as a porous carbon membrane of a symmetrical or asymmetrical construction or a porous carbon-containing inorganic membrane.

12. Method according to claim 1, characterized in that a microporous conductive carbon layer with a high inner surface is produced by pyrolysis of a polyfurfuryl alcohol resin in the pores or on the surface of a ceramic carrier material before the CVD deposition of the catalytically active constituents.

13. Method according to claim 1, characterized in that the substrate to be coated is an inorganic porous catalyst carrier in pellet form, for example, made of aluminum oxide, zirconium dioxide, silicon dioxide, titanium dioxide, magnesium oxide or of another material frequently used as a catalyst carrier.

14. Method according to claim 1, characterized in that the deposition site on a nonporous or porous carrier material is controlled in a targeted manner by the non-uniformly distributed use of the organic solubilizer before the deposition.

15. Method according to claim 1, characterized in that the deposition depth in a porous carrier material is controlled in a targeted manner by the use of a defined quantity of the organic solubilizer before the deposition.

16. Method according to claim 1, characterized in that shell catalysts are produced by controlling the deposition depth of the catalytic constituents in a porous carrier material in pellet form.

17. Method according to claim 1, characterized in that noble methods, such as palladium, platinum, rhodium, silver or gold are used as catalytically active constituents.

18. Method according to claim 1, characterized in that secondary group metals, such as nickel, copper, zinc or tin are used as catalytically active constituents.

19. Method according to claim 1, characterized in that metallic compounds, which are created during the disintegration of the organometallic parent compounds or by a subsequent aftertreatment of the deposited metals are used as catalytically active constituents.
